(19) United States
(12) Patent Application Publication
(10) Pub. No.: US 2025/0191875 A1
(43) Pub. Date: Jun. 12, 2025

(54) VACUUM CHAMBER SYSTEM INCLUDING TEMPERATURE CONDITIONING PLATE

(71) Applicant: ASML Netherlands B.V., Veldhoven (NL)

(72) Inventors: Dongchi YU, San Jose, CA (US); Jun-li LIN, San Jose, CA (US); Shao-Wei FU, San Jose, CA (US); Yi-Chen LIN, San Jose, CA (US); Hongbo FAN, San Jose, CA (US)

(73) Assignee: ASML Netherlands B.V., Veldhoven (NL)

(21) Appl. No.: 18/845,206

(22) PCT Filed: Feb. 10, 2023
(86) PCT No.: PCT/EP2023/053297

§ 371 Date: Sep. 9, 2024

Related U.S. Application Data
(60) Provisional application No. 63/319,212, filed on Mar. 11, 2022.

(51) Int. Cl. H01J 37/20; H01J 37/16; H01J 37/28

(52) U.S. Cl. CPC H01J 37/20; H01J 37/16; H01J 37/28; H01J 2237/002

(57) ABSTRACT

A vacuum chamber system comprises a supporting structure configured to support an object to be thermally stabilized, a plate, having a first surface facing the object, positioned such that the first surface is located within a predetermined distance from the object when the object is placed on the supporting structure, the plate being thermally coupled to a heat conduction source, and a chamber enclosing the supporting structure and the plate.

### CROSS-REFERENCE TO RELATED APPLICATIONS

This application claims priority of U.S. application 63/319,212 which was filed on 11 Mar. 2022 and which is incorporated herein in its entirety by reference.

### FIELD

The embodiments provided herein disclose a vacuum chamber system, and more particularly, a vacuum chamber system including a temperature conditioning plate.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed.

The SEM can have various vacuum chambers. A fast pumping down process can be utilized for vacuum chambers of the SEM to enhance system throughput. However, a fast pumping down process may cause a sudden temperature variation or a resultant low temperature in vacuum chambers, which can cause thermal drifting issues on wafers or damage delicate components of the SEM.

### SUMMARY

The embodiments provided herein disclose a vacuum chamber system, and more particularly, a vacuum chamber system including a temperature conditioning plate.

Some embodiments provide a vacuum chamber system. The system comprises a supporting structure configured to support an object to be thermally stabilized, a plate, having a first surface facing the object, positioned such that the first surface is located within a predetermined distance from the object when the object is placed on the supporting structure, the plate being thermally coupled to a heat conduction source, and a chamber enclosing the supporting structure and the plate.

Some embodiments provide an apparatus for attenuating a temperature variation on a wafer in a load-lock system during a pumping down process. The apparatus comprises a wafer holder configured to support the wafer, a plate, having a first surface facing the wafer, positioned such that the first surface is located within a predetermined distance from the wafer when the wafer is placed on the wafer holder, the plate being thermally coupled to a heat conduction source, and a chamber enclosing the wafer holder and the plate.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF THE DRAWINGS

The above and other aspects of the present disclosure will become more apparent from the description of exemplary embodiments, taken in conjunction with the accompanying drawings.

FIG. 1A is a schematic diagram illustrating an example charged-particle beam inspection system, consistent with embodiments of the present disclosure.

FIG. 1B is a schematic diagram illustrating an example wafer loading sequence in the charged-particle beam inspection system of FIG. 1A, consistent with embodiments of the present disclosure.

FIG. 2 is a schematic diagram illustrating an example electron beam tool, consistent with embodiments of the present disclosure that may be a part of the charged-particle beam inspection system of FIG. 1A.

FIG. 3 is an illustration of a conventional vacuum chamber system.

FIG. 4 is an illustration of an example vacuum chamber system including a temperature conditioning plate, consistent with embodiments of the present disclosure.

FIG. 5A is an illustration of a first surface of an example temperature conditioning plate of FIG. 4, consistent with embodiments of the present disclosure.

FIG. 5B is an illustration of a second surface of an example temperature conditioning plate of FIG. 4, consistent with embodiments of the present disclosure.

FIG. 5C is an illustration of a separation gap between a temperature conditioning plate and a protection object, consistent with embodiments of the present disclosure.

FIG. 6 is an illustration of an example load lock system including a temperature conditioning plate, consistent with embodiments of the present disclosure.

FIG. 7A is a graph illustrating heat flux variations on a protection object in a vacuum chamber with and without a temperature conditioning plate.

FIG. 7B is a graph illustrating temperature variations on a protection object in a vacuum chamber with and without a temperature conditioning plate.

FIG. 8A is a graph illustrating a saturation ratio during a pumping down process in a vacuum chamber without a temperature conditioning plate.

FIG. 8B is a graph illustrating a saturation ratio during a pumping down process in a vacuum chamber with a temperature conditioning plate according to some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or any system for generating images of surfaces or sub-surface structures using radiation technologies.

Electronic devices are constructed of circuits formed on a piece of semiconductor material called a substrate. The semiconductor material may include, for example, silicon, gallium arsenide, indium phosphide, silicon germanium, or any material having electrical properties between those of a conductor and an insulator. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

While high process yield is desirable in an IC chip manufacturing facility, it is also essential to maintain a high wafer throughput, defined as the number of wafers processed per hour. High process yields and high wafer throughput can be impacted by the presence of defects, especially when there is operator intervention to review the defects. Thus, high throughput detection and identification of micro and nano-sized defects by inspection tools (e.g., an SCPM) is essential for maintaining high yields and low cost.

The SEM can be configured to have various vacuum chambers, such as a load lock chamber, a MEMS chamber, or a secondary electron detection chamber in addition to a main chamber in which a wafer is inspected. Vacuum chambers can be quickly pumped down from atmospheric pressure (e.g., about 760 Torr) to a certain degree of pressure (e.g., about 0.01 Torr) to improve overall system efficiency. For example, a fast pumping down process may considerably benefit system throughput by expediting a wafer exchange or may increase system availability by reducing system downtime for maintenance or troubleshooting operations. As pressure drops quickly in a vacuum chamber during a fast pumping down process, a temperature of a gas in the vacuum chamber may also drops (e.g., more than 20 Kelvin) within a short period of time. To restore thermal equilibrium, heat energy could be introduced into the vacuum chamber via, for example, a chamber wall. A chamber wall of a vacuum chamber has a significant thermal mass, which enables the wall to maintain a fairly constant temperature even when the temperature of the gas in the chamber fluctuates. However, the heat loss of the gas caused by the pumping down process may not be fully recovered because of a relatively slow heat conduction rate via the chamber wall. Accordingly, a fast pumping down process may result in a sudden temperature drop in a vacuum chamber, which in turn may cause a substantial temperature drop of an object(s) that is in contact with the gas cooled down during the pumping down process. Such a temperature variation or drop may cause a thermal drifting issue on a wafer, which can cause the wafer to expand or contract in size sufficiently to increase the difficulty of determining the location of a defect, or may damage delicate components sensitive to a temperature variation or a low temperature. The sudden temperature drop may further increase particle contamination risks in a vacuum chamber resulting from condensation and condensation induced particle formation.

Embodiments of the present disclosure may provide an improved design for a vacuum chamber system. A vacuum chamber system according to some embodiments of the present disclosure may include a temperature conditioning plate, which is thermally coupled to a heat conduction source, located within a predetermined distance from a temperature sensitive object in a vacuum chamber. According to some embodiments, by locating a temperature conditioning plate in proximity to a temperature sensitive object, a temperature variation on the object can be attenuated during a fast pumping down process and thereby the object can be thermally stabilized. According to some embodiments, a surface of a temperature conditioning plate that faces a temperature sensitive object can include structures configured to enhance heat transfer between the surface and a gas that is located between the surface and the temperature sensitive object. By optimizing a distance between a temperature conditioning plate and a temperature sensitive object, a desired temperature attenuation effect on the object can be achieved during a pumping down process.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

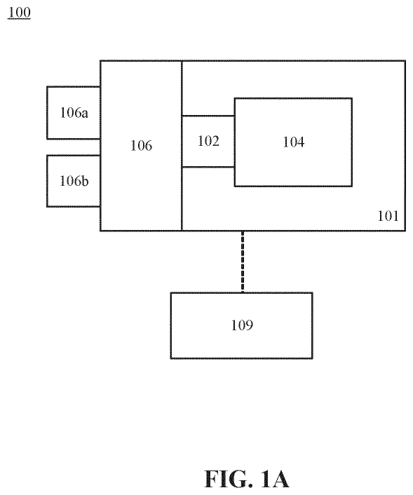

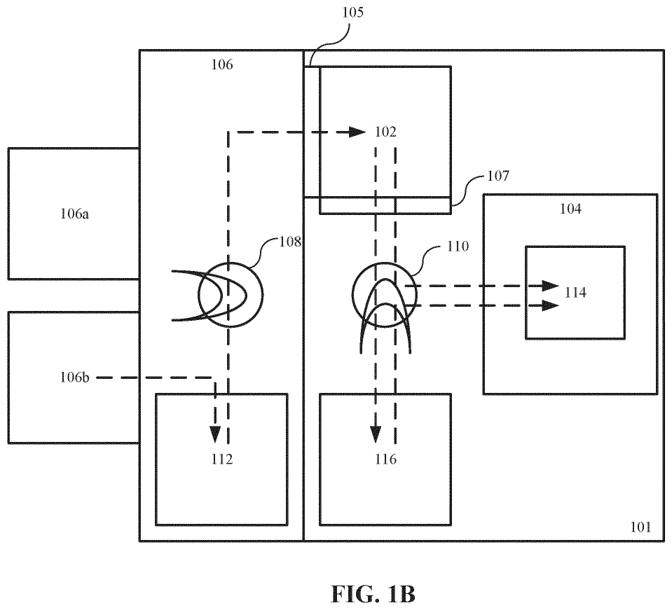

FIG. 1A illustrates an example charged-particle beam inspection system 100 consistent with embodiments of the present disclosure. system 100 may be used for imaging. As shown in FIG. 1A, system 100 includes a main chamber 101, a load-lock chamber 102, a beam tool 104, and an equipment front end module (EFEM) 106. Beam tool 104 is located within main chamber 101 and may be a single-beam system or a multi-beam system. EFEM 106 includes loading ports 106a and 106b. EFEM 106 may include additional loading port(s). Loading ports 106a and 106b may receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch. One or more robotic arms (not shown in FIG. 1A) in EFEM 106 may transport the wafers to load-lock chamber 102.

A controller 109 is electronically connected to beam tool 104. Controller 109 may be a computer configured to execute various controls of system 100. While controller 109 is shown in FIG. 1A as being outside of the structure that includes main chamber 101, load-lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

FIG. 1B is a schematic diagram illustrating an example wafer loading sequence in system 100 of FIG. 1A, consistent with embodiments of the present disclosure. In some embodiments, charged-particle beam inspection system 100 may include a robot arm 108 located in EFEM 106 and a robot arm 110 located in main chamber 101. Load-lock chamber 102 may be attached to EFEM 106 via a gate valve 105 and may be attached to main chamber 101 with a gate valve 107. In some embodiments, EFEM 106 may also include a pre-aligner 112 configured to position a wafer accurately before transporting the wafer to load-lock chamber 102.

In some embodiments, loading ports 106a and 106b may receive FOUPs. Robot arm 108 in EFEM 106 may transport the wafers from any of the loading ports 106a or 106b to pre-aligner 112 for assisting with the positioning. Pre-aligner 112 may use mechanical or optical aligning methods to position the wafers. After pre-alignment, robot arm 108 may transport the wafers to load-lock chamber 102 via gate valve 105.

Load-lock chamber 102 may include a sample holder (e.g., a supporting structure, not shown) that can hold one or more wafers. After the wafers are transported to load-lock chamber 102, a load-lock vacuum pump (not shown) may remove gas molecules in load-lock chamber 102 to reach a first pressure below the atmospheric pressure. After reaching the first pressure, a robot arm 110 may transport the wafer via gate valve 107 from load-lock chamber 102 to a wafer stage 114 of beam tool 104 in main chamber 101. Main chamber 101 is connected to a main chamber vacuum pump system (not shown), which may remove gas molecules in main chamber 101 to reach a second pressure below the first pressure. After reaching the second pressure, the wafer may be subject to inspection by beam tool 104.

In some embodiments, main chamber 101 may include a parking station 116 configured to temporarily store a wafer before inspection. For example, when the inspection of a first wafer is completed, the first wafer may be unloaded from wafer stage 114, and then a robot arm 110 may transport a second wafer from parking station 116 to wafer stage 114. Afterwards, robot arm 110 may transport a third wafer from load-lock chamber 102 to parking station 116 to store the third wafer temporarily until the inspection for the second wafer is finished.

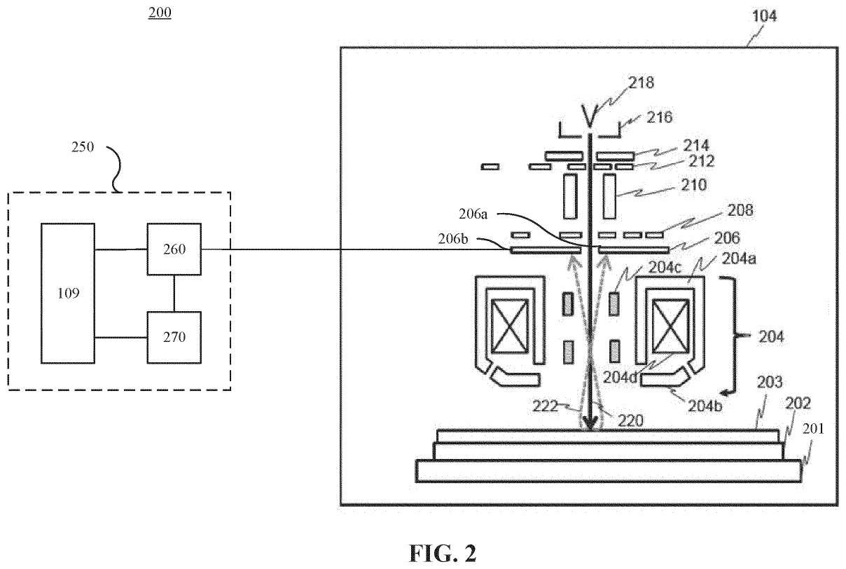

FIG. 2 illustrates an example imaging system 200 according to embodiments of the present disclosure. Electron beam tool 104 of FIG. 2 may be configured for use in system 100. Electron beam tool 104 may be a single beam apparatus or a multi-beam apparatus. As shown in FIG. 2, electron beam tool 104 includes a motorized sample stage 201, and a wafer holder 202 supported by motorized sample stage 201 to hold a wafer 203 to be inspected. Electron beam tool 104 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an Energy Dispersive X-ray Spectrometer (EDS) detector (not shown) to characterize the materials on wafer 203.

A primary electron beam 220 is emitted from cathode 218 by applying an acceleration voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may generate multiple primary electron beams 220, and electron beam tool 104 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, or any signal indicative of an electrical property) that represents an intensity of the beam spot and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes an electron beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of electron beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or any image properties. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

A charged-particle beam inspection system (e.g., a charged-particle beam inspection system 100 of FIG. 1A) may be configured to have various vacuum chambers such as a load lock chamber, a MEMs chamber, or a secondary electron detection chamber in addition to a main chamber. While operating the system, depressurization (“pumping down”) or pressurization (“venting up”) operations can be performed to vacuum chambers. The “depressurization,” as used herein, may refer to processes or procedures for decreasing gas pressure in an enclosed space (e.g., a chamber), such as by pumping gas out of the enclosed space. The “pressurization,” as used herein that may also be referred to as “re-pressurization,” may refer to processes or procedures for increasing gas pressure in an enclosed space (e.g., a chamber), such as by pumping gas into the enclosed space. Without limiting the scope of the present disclosure, some embodiments may be described in the context of vacuum chambers in a charged-particle beam inspection system. However, it will be appreciated that the disclosure is not so limited and can be applied to any types of vacuum chambers including a temperature sensitive object(s). One such example is a vacuum chamber of a lithography system.

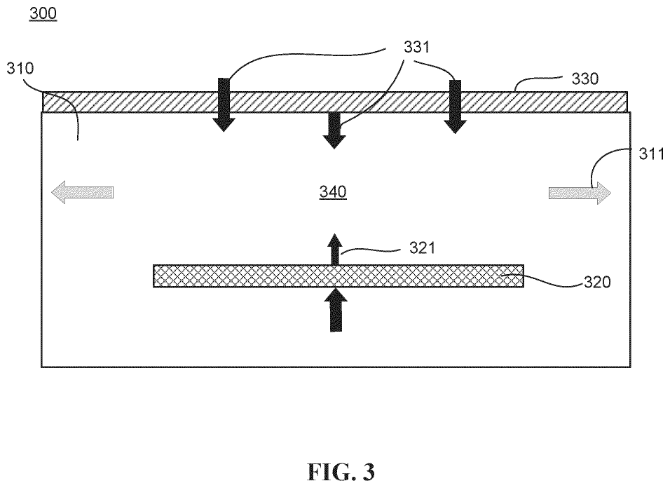

FIG. 3 is an illustration of a conventional vacuum chamber system. In FIG. 3, a vacuum chamber system 300 includes a chamber 310 that includes an object 320. Chamber 310 may enclose one or more supporting structures (not shown). The supporting structures may be used to support object 320. Chamber 310 may be enclosed by a chamber wall 330. While FIG. 3 illustrates chamber wall 330 on an upper side of chamber 310, chamber wall 330 may surround an entire perimeter of chamber 310. Chamber wall Chamber 310 may further include a gas vent (not shown). The gas vent may be used to vent a gas into chamber 310 (e.g., in a pressurization operation).

Vacuum chamber system 300 can be connected to a vacuum pump system such as a turbo pump (not shown), which removes a gas out of chamber 310 (e.g., in a depressurization operation) with a high flow rate. During a fast pumping down process, a gas 340 flows out of chamber 310 as indicated by a gas flow 311 in FIG. 3A. Thereby gas pressure of chamber 310 could quickly drop, which means that a substantial amount of a gas and an energy that the gas carries can be lost from chamber 310 during the fast pumping down process. Such a pressure drop may lead a sudden temperature drop in chamber 310. As a temperature of gas 340 drops in chamber 310, heat energy from chamber wall 330 is transferred to gas 340 via heat conduction as indicated by a heat arrow 331 to restore thermal equilibrium. It can be assumed that a temperature of chamber wall 330 can be maintained at a near-constant value (e.g., near-constant environmental value) without being affected by a temperature variation in chamber 310. Because a heat conduction speed through chamber wall 330 is relatively slow and a gas mass of gas 340 between object 320 and chamber wall 330 is relatively large, heat energy transferred from chamber wall 330 may not be sufficient to compensate the heat loss of gas 340 during the pumping down process. Therefore, heat energy from object 320 is also transferred to gas 340 as indicated by a heat arrow 321 to restore thermal equilibrium, which in turn drops a temperature of object 320 during the pumping down process. Such a temperature drop of object 320 can be aggravated as the pumping down speed increases. Further, a temperature drop of object 320 can be aggravated as a size of a vacuum chamber decreases.

As discussed with respect to FIG. 3, a fast pumping down process to a vacuum chamber can cause a sudden temperature drop inside chamber 310, which can result in a substantial temperature drop of a surface of object 310 that makes direct contact with gas 340 cooled down by the pumping down process. Such a temperature drop of object 320 may cause irreparable or serious harms when object 320 is temperature sensitive, such as a wafer, temperature delicate components of the system, etc. For example, a substantial temperature variation or a low temperature can cause thermal-drifting issues on a wafer in later processes, damage delicate components sensitive to temperature variations (e.g., aperture array of the SEM), or form particulate contaminants via water vapor condensation due to the sudden temperature drop and turbulent agglomeration. In practice, slowing down a speed of a pumping down process have been considered to alleviate the cooling effects such as the temperature variation or the resultant low temperature, but such measures will degrade overall system throughput caused by a longer pumping down time.

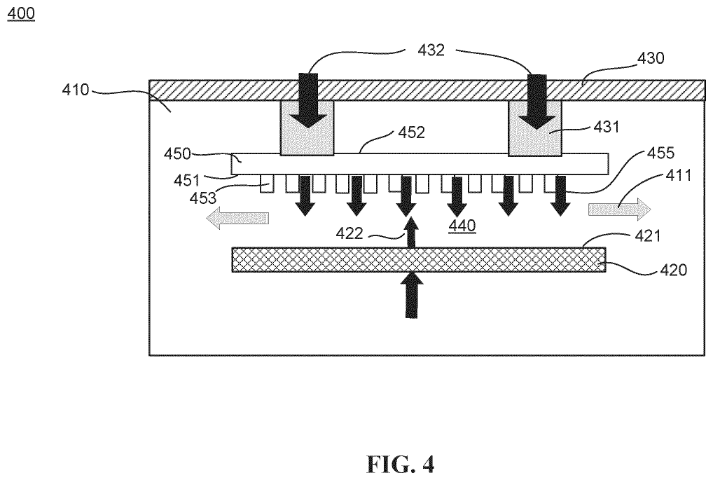

FIG. 4 is an illustration of an example vacuum chamber system including a temperature conditioning plate, consistent with embodiments of the present disclosure. According to some embodiments of the present disclosure, a vacuum chamber system 400 includes a chamber 410, an object 420, and a plate 450.

According to some embodiments of the present disclosure, chamber 410 may further enclose supporting structures (not shown). The supporting structures may be used to support object 420. In some embodiments, object 420 can be an object to be thermally stabilized or to be protected from temperature variations or a low temperature. In some embodiments, object 420 may include a temperature sensitive or temperature variation sensitive object(s) such as a wafer. In some embodiments, object 420 may include a temperature sensitive or temperature variation sensitive components (e.g., in charged-particle beam inspection system of FIG. 1A) such as electronic sensors, electron detectors, an aperture array, any temperature sensitive components, etc. In some embodiments, object 420 may have a surface 421 that directly contacts a gas 440 to be cooled down during a pumping down process. When object 420 is a wafer, surface 421 is a front surface of a wafer on which circuits are formed. It is noted that, although object 420 is shown in FIG. 4 for ease of explanation, vacuum chamber system 400 may or may not include object 420.

According to some embodiments of the present disclosure, plate 450 is installed to be located within a predetermined distance from object 420 when object 420 is placed on the supporting structure in chamber 410. In some embodiments, plate 450 can be made of a material(s) with high thermal conductivity. For example, plate 450 can be made with metal such as copper. In some embodiments, plate 450 can be a metal plate. In some embodiments, plate 450 is configured to be thermally coupled to a heat conduction source 430. In some embodiments, heat conduction source 430 can be positioned outside of chamber 410 and in contact with an environment that is at near-constant temperature. In some embodiments, heat conduction source 430 can be a component of vacuum chamber system 400 that is in contact with an environment outside of chamber 410. In some embodiments, heat conduction source 430 can have a near constant temperature without being affected by a temperature variation inside chamber 410 during a pumping down process. In some embodiments, heat conduction source 430 can have a large thermal mass such that it can be assumed that heat conduction source 430 is maintained at a near-constant temperature when heat energy is transferred from heat conduction source 430 to plate 450. In some embodiments, chamber 410 may be enclosed by a chamber wall, and the chamber wall can be utilized as heat conduction source 430 for plate 450. While FIG. 4 illustrates a chamber wall as heat conduction source 430 on an upper side of chamber 410, a chamber wall may surround an entire perimeter of chamber 410 or a partial perimeter of chamber 410.

According to some embodiments of the present disclosure, vacuum chamber system 400 may further include a thermal conduction block 431. In some embodiments, thermal conduction block 431 is configured to thermally couple plate 450 and heat conduction source 430 as shown in FIG. 4. In some embodiments, thermal conduction block 431 can be made of a material(s) with high thermal conductivity. For example, thermal conduction block 431 can be made with metal such as copper. In some embodiments, thermal conduction block 431 can include a thermal conduction structure embedded therein. For example, thermal conduction block 431 can include heat pipe(s) of which two end terminals are configured to be in contact with plate 450 and heat conduction source 430, respectively. In some embodiments, thermal conduction block 431 can further be heated by an active heat source such as a heater (not shown) in addition to be connected to heat conduction source 630. For example, thermal conduction block 431 is connected to an active heat source on its external end outside of chamber 410.

According to some embodiments, plate 450 can have a size that substantially covers surface 421 of object 420. In some embodiments, plate 450 can have the same size as surface 421 of object as shown in FIG. 4. For example, margins of plate 450 may be off from margins of object 420 within a positive or negative error tolerance. In some embodiments, plate 450 has a shape corresponding to a shape of surface 421 of object 420. For example, when surface 421 has a round shape, plate 450 can be configured to have a round shape. In some embodiments, plate 450 can be installed to be substantially parallel to surface 421 of object 420. By installing plate 450 to be substantially parallel to surface 421 of object 420, heat can be uniformly transferred to an area of surface 421.

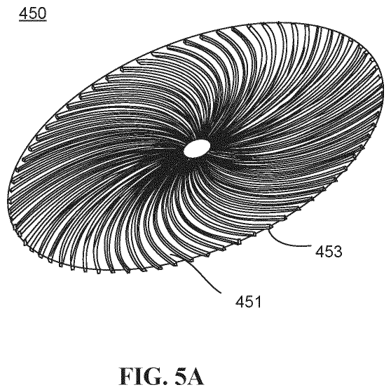

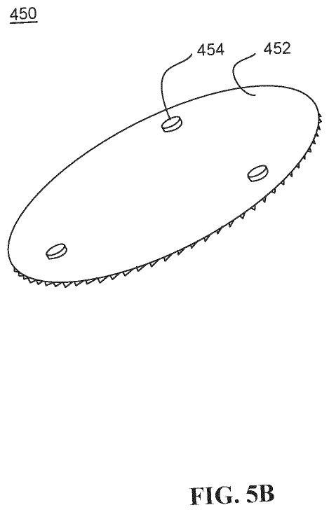

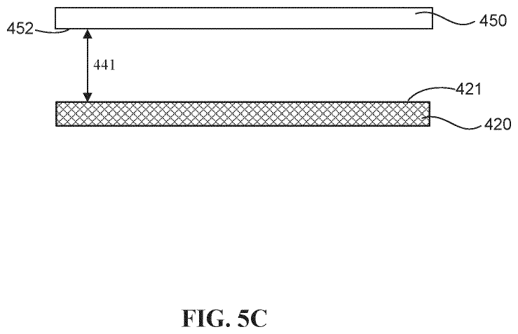

According to some embodiments of the present disclosure, plate 450 has a first surface 451 and a second surface 452. As shown in FIG. 4, first surface 451 of plate 450 may be a surface facing surface 421 of object 420. In some embodiments, first surface 451 of plate 450 can be configured to have structures 453 that can facilitate heat transfer between first surface 451 and gas 440 that is between first surface 451 of plate 450 and surface 421 of object 420. In some embodiments, structures 453 can be fins, pillars, grooved strips, or raised strips, or any other three-dimensional structures that can increase a surface area of first surface 452. FIG. 5A is an illustration of first surface 451 of plate 450 of FIG. 4, consistent with embodiments of the present disclosure. As shown in FIG. 5A, first surface 451 includes structures 453 that can enhance heat transfer from plate 450. In FIG. 5A, structures 453 have radially or vortically extended strips that can increase a surface area of first surface 451 and thus can enhance heat transfer from plate 450 to a gas in contact with first surface 451. While FIG. 5A illustrates first surface 451 having structures 453 of radially or vortically extended strips, it will be appreciated that a shape of structures 453 are not limited to structures 453 illustrated in FIG. 5B. Any structures that increase a surface area on first surface 451 can be applicable for some embodiments of the present disclosure.

Referring back to FIG. 4, second surface 452 of plate 450 may be a surface facing away from surface 421 of object 420. In some embodiments, plate 450 can thermally be coupled to heat conduction source 430 via second surface 452 as shown in FIG. 4. FIG. 5B is an illustration of second surface 452 of plate 450 of FIG. 4, consistent with embodiments of the present disclosure. As shown in FIG. 5B, second surface 452 of plate 450 may be configured to have a receptor 454 for connecting or fixing plate 450 to thermal conduction block 431. In some embodiments, receptor 454 can be configured to accommodate thermal conduction block 431 and to fix plate 430 to thermal conduction block 431. While FIG. 5B illustrates three receptors 454 on second surface 452, it will be appreciated that any number of receptors 454 can be applicable for some embodiments of the present disclosure.

Referring back to FIG. 4, according to some embodiments of the present disclosure, plate 450 can be installed to be located within a predetermined distance from object 420 when object 420 is placed on the supporting structure in chamber 410. In some embodiments, plate 450 can be positioned in proximity to surface 421. According to some embodiments of the present disclosure, a separation gap (e.g., a predetermined distance) between plate 450 and object 420 can be determined according to a degree of an acceptable temperature variation on surface 421 of object 420. FIG. 5C is an illustration of a separation gap between plate 450 and object 420, consistent with embodiments of the present disclosure. As shown in FIG. 5C, a separation gap 441 between plate 450 and object 420 can be a distance between first surface 451 of plate 450 and surface 421 of object 420. By placing plate 450 in proximity to surface 421, a gas mass of gas 440 between plate 450 and object 420 can be reduced, which in turn implies that a less amount of heat can compensate a heat loss of gas 440 during a pumping down process. In some embodiments, a certain level of separation gap 441 between plate 450 and object 420 can be maintained so as to achieve a certain level of a temperature variation attenuation effect on surface 421. In some embodiments, separation gap 441 between plate 450 and object 420 can be maintained less than approximately 15 mm so as to achieve a temperature variation less than 7 K/s (Kevin/sec) on surface 421. In some embodiments, separation gap 441 can be maintained less than approximately 10 mm so as to achieve a temperature variation less than 5 K/s on surface 421. In some embodiments, separation gap 441 can be maintained less than approximately 5 mm so as to achieve a temperature variation less than 2 K/s on protection surface 421. It will be appreciated that a relationship between a separation gap and a temperature variation attenuation effect can change depending on a vacuum chamber size, a pumping down speed, a material of plate 450, a material of thermal conduction block 431, a distance between plate 450 and heat conduction source 430, a heat conduction rate of heat conduction source 430, etc.

Referring back to FIG. 4, vacuum chamber system 400 can be connected to a vacuum pump system such as a turbo pump (not shown), which removes a gas out of chamber 410 (e.g., in a depressurization operation) with a high flow rate. According to some embodiments, by installing plate 450 inside chamber 410 as shown in FIG. 4, sudden temperature variations or low temperatures during a fast pump-down process of vacuum chamber 400 can be alleviated. In some embodiments, as plate 450 is connected to heat conduction source 430 of which temperature is not affected by a pumping down process, a temperature of plate 450 can also be maintained at a near constant temperature via thermal conduction block 431. In some embodiments, as plate 450 has a large surface area on first surface 451 facing surface 421, thermal convection from plate 450 to gas 440 between plate 450 and surface 421 can be facilitated. Moreover, as plate 450 is installed in proximity to surface 421, a gas mass of gas 440 between plate 450 and object 420 can be reduced compared to a gas mass of gas 340 of FIG. 3, which in turn implies that a less amount of heat can compensate a heat loss of gas 440 during a pump-down process. According to some embodiments of the present disclosure, as gas 440 can be heated up rapidly by plate 450 via thermal conduction block 431 and heat conduction source 430, heat transfer from surface 421 to gas 440 can be reduced or minimized. According to some embodiments of the present disclosure, surface 421 of object 420 can be protected from a sudden temperature variation/drop or a resultant low temperature caused by a fast pumping down process.

It will be appreciated that vacuum chamber system 400 shown in FIG. 4 can be applicable to any vacuum chamber having any temperature sensitive object(s). The present disclosure can be applicable to a load-lock system (e.g., including a load-lock chamber 102 of FIG. 1A) as a fast pumping down process can be used to a load-lock chamber so as to expedite a wafer exchange process. A wafer may be a temperature sensitive object because a wafer may expand or contract depending on a temperature. When a wafer size changes due to thermal expansion or contraction, it is difficult to accurately map a wafer to a reference design or a reference wafer, which leads to errors in detecting defect(s) on a wafer or in measuring critical dimensions. Therefore, it is preferable to minimize a temperature variation on a wafer(s) for later processes.

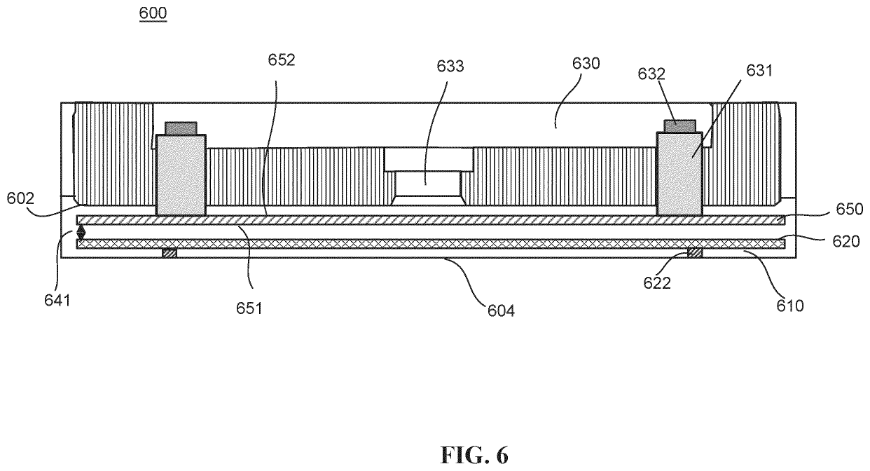

FIG. 6 is an illustration of an example load lock system including a thermal conditioning plate, consistent with embodiments of the present disclosure. In FIG. 6, a load-lock system 600 includes a chamber 610 that includes a ceiling 602 and a floor 604. Chamber 610 may enclose one or more supporting structures (e.g., wafer seats) arranged on floor 604, including supporting structure 622. Supporting structures 622 may be used to support a wafer 620. It is noted that, although wafer 620 is shown in FIG. 6 for ease of explanation, load-lock system 600 may or may not include wafer 620.

According to some embodiments of the present disclosure, load-lock system 600 further includes a plate 650, a heat conduction source 630, and a thermal conduction block 631. In some embodiments, plate 650 can be plate 450 of FIG. 4. Heat conduction source 630 can be heat conduction source 430 of FIG. 4, and thermal conduction block 631 can be thermal conditioning block 431 of FIG. 4. Descriptions of plate 650, heat conduction source 630, and thermal conduction block that are described with respect to FIG. 4 including plate 450, heat conduction source 430, and thermal conduction block 431 will be omitted here.

According to some embodiments, plate 650 is installed to be located within a predetermined distance from wafer 620. In some embodiments, plate 650 is configured to be thermally coupled to heat conduction source 630. In some embodiments, heat conduction source 630 can be positioned outside of chamber 610 and in contact with an environment that is at near-constant temperature. As shown in FIG. 6, chamber 610 may be enclosed by a chamber wall, and the chamber wall can be utilized as heat conduction source 630 for plate 650. In FIG. 6, ceiling 602 is positioned between chamber 610 and heat conduction source 630. It will be noted that the ceiling 602 is in contact with chamber 610 and may be affected by a temperature variation inside chamber 610.

According to some embodiments of the present disclosure, thermal conduction block 631 is configured to thermally couple plate 650 and heat conduction source 630 as shown in FIG. 6. In some embodiments, thermal conduction block 431 can be made of a material(s) with high thermal conductivity. In some embodiments, load lock system 600 may further include an active heat source 632 configured to heat thermal conduction block 631. In some embodiments, active heat source 632 can be a heater and can be connected to an external end of thermal conduction block 631 outside of chamber 610.

According to some embodiments, plate 650 can have a size that substantially covers a wafer surface of wafer 620. In some embodiments, plate 650 can have the same size as wafer 620 as shown in FIG. 6. For example, margins of plate 650 may be off from margins of wafer 620 within a positive or negative error tolerance. In some embodiments, plate 650 has a shape corresponding to a shape of wafer 620. For example, when wafer 620 has a round shape, plate 650 can be configured to have a round shape. In some embodiments, plate 650 can be installed to be substantially parallel to wafer 620 as shown in FIG. 6. By installing plate 650 to be in parallel to wafer 620, heat can be uniformly transferred to a surface of wafer 620.

According to some embodiments of the present disclosure, plate 650 has a first surface 651 and a second surface 652. As shown in FIG. 6, first surface 651 of plate 650 may be a surface facing wafer 620. In some embodiments, first surface 651 of plate 650 can be configured to have structures that can facilitate heat transfer between first surface 651 and a gas that is between first surface 651 of plate 650 and wafer 620. Any structures that increase a surface area on first surface 651 can be applicable for some embodiments of the present disclosure. As shown in FIG. 6, second surface 652 of plate 650 may be a surface facing away from wafer 620. In some embodiments, plate 650 can thermally be coupled to heat conduction source 630 via second surface 652 as shown in FIG. 6. In some embodiments, second surface 652 of plate 650 may be configured to have a receptor(s) (e.g., receptor 454 in FIG. 5B) for connecting plate 650 to thermal conduction block 631.

In some embodiments, plate 650 can be positioned in proximity to wafer 620. According to some embodiments of the present disclosure, a separation gap 641 (e.g., a predetermined distance) between plate 650 and wafer 620 can be determined according to a degree of an acceptable temperature variation on wafer 620. As shown in FIG. 6, a separation gap 641 between plate 650 and wafer 6420 can be a distance between first surface 651 of plate 650 and a wafer surface of wafer 620. In some embodiments, a certain level of separation gap 641 between plate 650 and wafer 620 can be maintained so as to achieve a certain level of a temperature variation attenuation effect on wafer 620. In some embodiments, separation gap 641 between plate 650 and wafer 620 can be maintained less than approximately 15 mm so as to achieve a temperature variation less than 7 K/s (Kevin/sec) on wafer 620. In some embodiments, separation gap 641 can be maintained less than approximately 10 mm so as to achieve a temperature variation less than 5 K/s on wafer 620. In some embodiments, separation gap 641 can be maintained less than approximately 5 mm so as to achieve a temperature variation less than 2 K/s on wafer 620.

As shown in FIG. 6, load-lock system 600 may further include a gas vent 633 at ceiling 602. Gas vent 633 may be used to vent gas into chamber 610 (e.g., in a pressurization operation).

According to some embodiments, load lock system 600 can be connected to a vacuum pump system such as a turbo pump (not shown), which removes a gas out of chamber 610 (e.g., in a depressurization operation) with a high flow rate. According to some embodiments, by installing plate 650 inside chamber 610 as shown in FIG. 6, sudden temperature variations or low temperatures in chamber 621 during a fast pumping down process can be alleviated. According to some embodiments of the present disclosure, wafer 620 can be protected from a sudden temperature variation/drop or a resultant low temperature caused by a fast pumping down process.

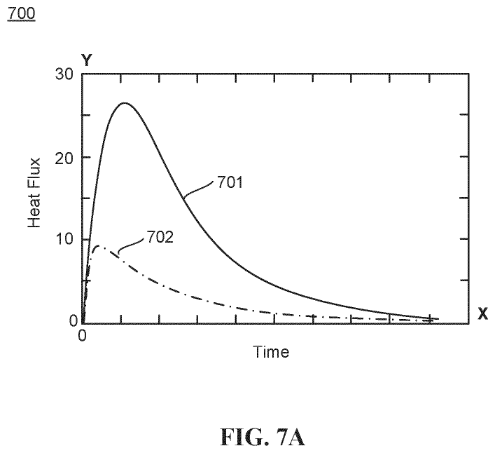

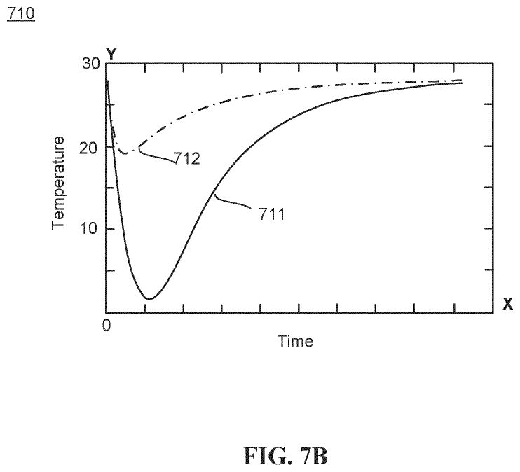

FIG. 7A is a graph illustrating heat flux variations on a protection surface (e.g., surface 421 of FIG. 4) to be thermally stabilized in a vacuum chamber with and without a temperature conditioning plate (e.g., plate 450 of FIG. 4). In graph 700, an x-axis represents an elapsed time from the beginning of a pump-down process for a vacuum chamber and y-axis represents heat flux on a protection surface. In FIG. 7A, a line 701 indicates heat flux measured on a protection surface over time in a vacuum chamber without a temperature conditioning plate. Line 701 is obtained by modeling a pumping down process under environments where a wafer is used as an object to be protected, a wafer has a size of 300 mm diameter, air is used as a gas in a vacuum chamber, and a distance between a chamber wall and a protection surface is 20 mm. A line 702 indicates heat flux measured on a protection surface over time in a vacuum chamber with a temperature conditioning plate according to some embodiments of the present disclosure. Line 702 is obtained by modeling a pumping down process under the same environments for line 701 except that the vacuum chamber includes a temperature conditioning plate, a separation gap between a temperature conditioning plate and a protection surface is 10 mm, and a ratio of a surface area of a temperature conditioning plate facing the protection surface to a surface area of a temperature conditioning plate facing away the protection surface is about 2.23. As shown in FIG. 7A, heat flux (e.g., indicated by line 702) on a protection surface is smaller in a vacuum chamber with a temperature conditioning plate compared to heat flux (e.g., indicated by line 701) in a vacuum chamber without a temperature conditioning plate. It is noted from FIG. 7A that a peak amplitude of heat flux on a protection surface is reduced about 70% by using a temperature conditioning plate in a vacuum.

FIG. 7B is a graph illustrating temperature variations on a protection surface (e.g., surface 421 of FIG. 4) to be thermally stabilized in a vacuum chamber with and without a temperature conditioning plate (e.g., plate 450 of FIG. 4). In graph 710, an x-axis represents an elapsed time from the beginning of a pump-down process for a vacuum chamber and y-axis represents a temperature on a protection surface. In FIG. 7B, a line 711 indicates a temperature measured on a protection surface over time in a vacuum chamber without a temperature conditioning plate. Line 711 is obtained by modeling a pumping down process under the same environments for obtaining graph 701 in FIG. 7A. A line 712 indicates a temperature measured on a protection surface over time in a vacuum chamber that includes a temperature conditioning plate according to some embodiments of the present disclosure. Line 712 is obtained by modeling a pumping down process under the same environments for obtaining line 702 in FIG. 7A. As shown in FIG. 7B, a temperature variation (e.g., indicated by line 712) on a protection surface is smaller in a vacuum chamber with a temperature conditioning plate compared to a temperature variation (e.g., indicated by line 711) in a vacuum chamber without a temperature conditioning plate. It is noted from FIG. 7B that a temperature variation on a protection surface is reduced about 70% by using a temperature conditioning plate in a vacuum. It is also noted from FIG. 7B that a lowest temperature on a protection surface during a pump-down process is increased by using a temperature conditioning plate in a vacuum.

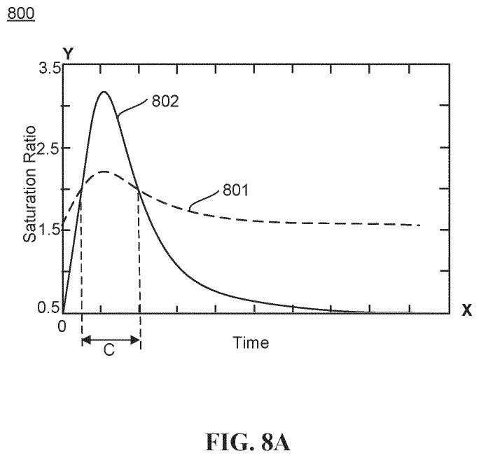

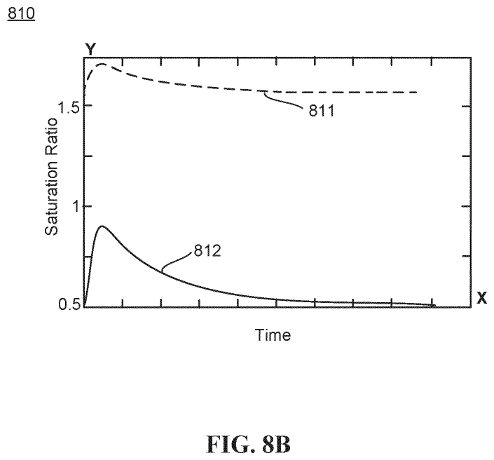

FIG. 8A is a graph illustrating a saturation ratio of gas during a pump-down process in a vacuum chamber without a temperature conditioning plate (e.g., plate 450 of FIG. 4). In graph 800, an x-axis represents an elapsed time from the beginning of a pump-down process for a vacuum chamber and y-axis represents a saturation ratio of gas in a vacuum chamber. Graph 800 is obtained by modeling a pumping down process under the same environments for obtaining graph 701 in FIG. 7A. In FIG. 8A, a line 801 indicates a critical saturation ratio for a critical particle radius over time in a vacuum chamber without a temperature conditioning plate. Line 802 indicates a saturation ratio of gas over time in a vacuum chamber without a temperature conditioning plate. As shown in FIG. 8A, a saturation ratio is higher than a critical saturation ratio at least for a time period C and is very close to a critical saturation ratio for a longer time period around period C, which can imply that it is likely to have risks of water vapor condensation and condensation-induced particle formation in a vacuum chamber.

FIG. 8B is a graph illustrating a saturation ratio of gas during a pump-down process in a vacuum chamber with a temperature conditioning plate (e.g., plate 450 of FIG. 4). In graph 810, an x-axis represents an elapsed time from the beginning of a pump-down process for a vacuum chamber and y-axis represents a saturation ratio of gas in a vacuum chamber. Graph 810 is obtained by modeling a pumping down process under the same environments for obtaining graph 702 in FIG. 7A. In FIG. 8B, a line 811 indicates a critical saturation ratio for a critical particle radius over time in a vacuum chamber with a temperature conditioning plate. Line 812 indicates a saturation ratio of gas over time in a vacuum chamber with a temperature conditioning plate. As shown in FIG. 8B, a saturation ratio is smaller than a critical saturation ratio throughout a pump-down process. In FIG. 8B, a gap between a saturation ratio and a critical saturation ratio is larger compared to that of graph 800 of FIG. 8A. It is noted that a peak saturation ratio value in FIG. 8B is about 25% of a peak saturation value of FIG. 8A, which can imply that a risk of condensation and an associated particle contamination can be reduced by using a temperature conditioning plate in a vacuum chamber. Please note that numerical values in graphs 700 of FIG. 7A, 710 of FIG. 7B, 800 of FIG. 8A, and 810 of FIG. 8B are used to show relative values rather than absolute values.

The embodiments may further be described using the following clauses:
1. A vacuum chamber system, comprising:
   a supporting structure configured to support an object to be thermally stabilized;
   a plate, having a first surface facing the object, positioned such that the first surface is located within a predetermined distance from the object when the object is placed on the supporting structure, the plate being thermally coupled to a heat conduction source; and
   a chamber enclosing the supporting structure and the plate.
2. The vacuum chamber system of clause 1, wherein the plate is substantially parallel to a surface of the object that faces the first surface.
3. The vacuum chamber system of clause 1 or 2, wherein the plate has a size to substantially cover a surface of the object.
4. The vacuum chamber system of any one of clauses 1-3, further comprising a thermal conduction block configured to connect the plate and the heat conduction source.
5. The vacuum chamber system of any one of clauses 4, wherein the thermal conduction block is a metal conduction block.
6. The vacuum chamber system of clause 4, further comprising a heater configured to provide heat energy to the thermal conduction block.
7. The vacuum chamber system of any one of clauses 1-6, wherein the heat conduction source is configured to be maintained at a near constant temperature during a pumping down process of the chamber.
8. The vacuum chamber system of any one of clauses 1-7, wherein the heat conduction source is a chamber wall surrounding the chamber.
9. The vacuum chamber system of any one of clauses 1-8, wherein the first surface includes structures configured to enhance heat transfer between the first surface and a gas that is between the first surface and the object.
10. The vacuum chamber system of clause 9, wherein the structures include fins, pillars, grooved strips, or raised strips.
11. The vacuum chamber system of any one of clauses 1 to 10, wherein the plate has a second surface facing away the object and the plate is thermally coupled to the heat conduction source via the second surface.
12. The vacuum chamber system of clause 11, wherein the first surface has a larger surface area than the second surface.
13. The vacuum chamber system of any one of clauses 1-12, wherein the predetermined distance is approximately 15 millimeters.
14. The vacuum chamber system of any one of clauses 1-13, wherein the object has a temperature variation less than 7 K/s during a pump-down process of the chamber.
15. The vacuum chamber system of any one of clauses 1-14, wherein the vacuum chamber system is a load lock system and the object is a wafer.
16. An apparatus for attenuating a temperature variation on a wafer in a load-lock system during a pumping down process, comprising:
   a wafer holder configured to support the wafer;
   a plate, having a first surface facing the wafer, positioned such that the first surface is located within a predetermined distance from the wafer when the wafer is placed on the wafer holder, the plate being thermally coupled to a heat conduction source; and
   a chamber enclosing the wafer holder and the plate.
17. The apparatus of clause 16, wherein the plate is substantially parallel to a surface of the wafer that faces the first surface.
18. The apparatus of clause 16 or 17, wherein the plate has a size to substantially cover a surface of the wafer.
19. The apparatus of any one of clauses 16-18, further comprising a thermal conduction block configured to connect the plate and the heat conduction source.
20. The apparatus of clause 19, wherein the thermal conduction block is a metal conduction block.
21. The apparatus of clause 19, further comprising a heater configured to provide heat energy to the thermal conduction block.
22. The apparatus of any one of clauses 16-21, wherein the heat conduction source is configured to be maintained at a near constant temperature during a pumping down process of the chamber.
23. The apparatus of any one of clauses 16-22, wherein the heat conduction source is a chamber wall surrounding the chamber.
24. The apparatus of any one of clauses 16-23, wherein the first surface includes structures configured to enhance heat transfer between the first surface and a gas that is between the first surface and the wafer.
25. The apparatus of clause 24, wherein the structures include fins, pillars, grooved strips, or raised strips.
26. The apparatus of any one of clauses 16 to 25, wherein the plate has a second surface facing away the wafer and the plate is thermally coupled to the heat conduction source via the second surface.
27. The apparatus of clause 26, wherein the first surface has a larger surface area than the second surface.
28. The apparatus of any one of clauses 16-27, wherein the predetermined distance is approximately 15 millimeters.
29. The apparatus of any one of clauses 16-28, wherein the wafer has a temperature variation less than 7 K/s during a pump-down process of the chamber.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A vacuum chamber system, comprising:
a supporting structure configured to support an object to be thermally stabilized;
a plate, having a first surface facing the object, positioned such that the first surface is located within a predetermined distance from the object when the object is placed on the supporting structure, the plate being thermally coupled to a heat conduction source; and
a chamber enclosing the supporting structure and the plate.

2. The vacuum chamber system of claim 1, wherein the plate is substantially parallel to a surface of the object that faces the first surface.

3. The vacuum chamber system of claim 1, wherein the plate has a size to substantially cover a surface of the object.

4. The vacuum chamber system of claim 1, further comprising a thermal conduction block configured to connect the plate and the heat conduction source.

5. The vacuum chamber system of claim 4, wherein the thermal conduction block is a metal conduction block.

6. The vacuum chamber system of claim 4, further comprising a heater configured to provide heat energy to the thermal conduction block.

7. The vacuum chamber system of claim 1, wherein the heat conduction source is configured to be maintained at a near constant temperature during a pumping down process of the chamber.

8. The vacuum chamber system of claim 1, wherein the heat conduction source is a chamber wall surrounding the chamber.

9. The vacuum chamber system of claim 1, wherein the first surface includes structures configured to enhance heat transfer between the first surface and a gas that is between the first surface and the object.

10. The vacuum chamber system of claim 9, wherein the structures include fins, pillars, grooved strips, or raised strips.

11. The vacuum chamber system of claim 1, wherein the plate has a second surface facing away the object and the plate is thermally coupled to the heat conduction source via the second surface.

12. The vacuum chamber system of claim 11, wherein the first surface has a larger surface area than the second surface.

13. The vacuum chamber system of claim 1, wherein the predetermined distance is approximately 15 millimeters.

14. The vacuum chamber system of claim 1, wherein the object has a temperature variation less than 7 K/s during a pump-down process of the chamber.

15. The vacuum chamber system of claim 1, wherein the vacuum chamber system is a load lock system and the object is a wafer.

16. An apparatus for attenuating a temperature variation on a wafer in a load-lock system during a pumping down process, comprising:
a wafer holder configured to support the wafer;
a plate, having a first surface facing the wafer, positioned such that the first surface is located within a predetermined distance from the wafer when the wafer is placed on the wafer holder, the plate being thermally coupled to a heat conduction source; and
a chamber enclosing the wafer holder and the plate.

17. The apparatus of claim 16, wherein the plate is substantially parallel to a surface of the wafer that faces the first surface.

18. The apparatus of claim 16, wherein the plate has a size to substantially cover a surface of the wafer.

19. The apparatus of claim 16, further comprising a thermal conduction block configured to connect the plate and the heat conduction source.

20. The apparatus of claim 19, wherein the thermal conduction block is a metal conduction block.
